(19) United States
(12) Patent Application Publication
(10) Pub. No.: US 2026/0110763 A1
(43) Pub. Date: Apr. 23, 2026

(54) HIGH-FREQUENCY BANDPASS FILTER FOR AN MR APPARATUS WITH COIL BODY HAVING A CAVITY, MR APPARATUS

(71) Applicant: Bruker Switzerland AG, Fällanden (CH)

(72) Inventors: Fabian SCHMITTER, Schwerzenbach (CH); Martin LUKE, Fällanden (CH); Arthur SCHWILCH, Gossau (CH)

(21) Appl. No.: 19/477,621

(22) PCT Filed: Apr. 18, 2024
(86) PCT No.: PCT/EP2024/060527

§ 371 Date: Oct. 22, 2025

(30) Foreign Application Priority Data
Apr. 28, 2023 (DE) 10 2023 203 996.6

(51) Int. Cl. G01R 33/36; H03H 7/01

(52) U.S. Cl. CPC G01R 33/3621; H03H 7/0161

(57) ABSTRACT

The invention relates to a radio-frequency bandpass filter for an MR apparatus, in particular for a transmission and/or receiving arrangement of the MR apparatus, comprising a resonator arrangement with a signal input, a signal output and at least one resonator, wherein each resonator has a capacitor which is connected in parallel to an inductor, characterized in that the inductor comprises an electrically conductive coil body having a cavity which is closed in a substantially RF-tight manner. As a result, an RF bandpass filter of high quality, high electric load-bearing capacity and simultaneously a low impedance level is achieved which can be produced simply and at low cost.

### BACKGROUND OF THE INVENTION

The invention relates to a radio-frequency bandpass filter for an MR apparatus, in particular for a transmission and/or receiving arrangement of the MR apparatus, comprising a resonator arrangement with a signal input, a signal output, and at least one resonator, wherein each resonator has a capacitor which is connected in parallel to an inductor.

For transmission and receiving devices of MR apparatuses, e.g., NMR spectrometers, bandpass filters with a frequency band in the two-to three-digit MHz range are required. Conventional bandpass filters for this task are typically manufactured by means of wound cylindrical coils and/or milled helical resonators in cast or milled housings on individual printed circuit boards. [1] discloses such a bandpass filter design. The frequency adjustment required due to tolerances is accomplished by trimming capacitors. The active and passive units are typically interconnected with coaxial cables and coaxial connectors. However, such bandpass filters require great manual effort in setting up the filters and in the subsequent adjustment. In addition, a variety of coils or helical resonators and trimming capacitors must be kept in stock, which increases manufacturing costs. The entire structure is also susceptible to mechanical shocks and vibrations and exhibits a certain temperature dependence.

### OBJECT OF THE INVENTION

The object of the invention is to propose a compact RF bandpass filter which is of high quality, has a high electrical load capacity, and at the same time a low impedance level and can be manufactured easily and inexpensively.

### DESCRIPTION OF THE INVENTION

This object is achieved by a radio-frequency bandpass filter according to claim 1, an MR apparatus according to claim 14, and the use of a resonator according to claim 15.

According to the invention, the inductor comprises an electrically conductive coil body having a cavity which is closed in a substantially RF-tight manner. Substantially “RF-tight” means that the magnetic field spreads within the coil body, and the stray field outside the coil body is minimal. The RF tightness is achieved by the shape and material selection of the coil body. In the resonator according to the invention, the magnetic flux is therefore kept substantially completely (>99%, preferably >99.9%) within the coil body so that the stray field outside the coil body is minimized.

Resonators having an inductor with a cavity are already used for various applications as detunable resonant circuits [2], [3], [4], [5], [6]. In this case, RF-tightness is not required and therefore also not provided.

In the present invention, the resonator is not used as a tunable resonant circuit, but as an RF filter, preferably with a fixed resonance frequency. Due to the shape of the resonator enclosing a cavity, it is of high quality and therefore has a high electrical resistance at the resonance frequency. The shape according to the invention and the associated large volume of the coil body result in both low electrical and low thermal resistance (outside the resonance frequency). This yields a high load capacity, in particular in combination with a high voltage strength of the capacitor.

The geometry according to the invention ensures a small inductance of the coil body and therefore, together with a large capacitance, a low impedance level.

Part of the bandpass filter according to the invention can be easily manufactured in the form of a flat module that can be assembled by machine. The flat module can contain additional active electronics for the MR apparatus (e.g., switches, amplifiers, etc.), which simplifies the design and is economical to manufacture.

The capacitance of the resonator can comprise one or more capacitors and forms an electrical resonant circuit with the coil body. The coil body is preferably metallic, in particular made of aluminum, and in a preferred embodiment has an electrically conductive outer wall and a central, electrically conductive support element which form a toroid-like cavity, for example. The coil body can, for example, be in the form of a milled or cast housing or a combination thereof.

The RF bandpass filter according to the invention can be used advantageously in particular for MR transmission and receiving devices, e.g., in conjunction with NMR probe heads.

Preferably, the cavity of the coil body is rotationally symmetrical with a toroidal surface, i.e., a surface of revolution that has a hole in the middle (axis of rotation runs through the hole and does not intersect the surface of revolution). The cross-section of the rotating body parallel to the axis of rotation can be of any shape and is preferably rectangular with rounded edges on at least one side. This results in a partially hollow cylindrical cavity. The axis of the hollow cylinder forms the resonator axis. “Partially hollow cylindrical” therefore includes, among other things, a cylinder with at least partially rounded edges. In this case, the cavity cross-section tapers parallel to the resonator axis, or the cavity cross-sections perpendicular to the resonator axis are different sizes for different positions along the resonator axis.

In a particularly preferred embodiment, the resonator has a cover element which, together with the coil body, delimits the cavity. The cover element is a substantially RF-tight flat element that is placed on the open place of the coil body. The cover element can be attached to the coil body, for example, by screwing, pressing, clamping, or soldering.

Preferably, the cover element is designed as a printed circuit board. Alternatively, another metal part (or metalized part) can be used as the cover element.

The cover element is preferably electrically insulating and is largely provided, in particular coated, with an electrically conductive material on the side facing the cavity.

Preferably, the side facing the cavity (underside) is completely coated with an electrically conductive material, with the exception of regions where capacitors may be provided. If the capacitors are arranged on the cover element, the cover element cannot be coated continuously since this would short-circuit the capacitors.

A continuously coated underside of the cover element can be provided, for example, if the capacitor is arranged in the support element (see below).

In a particularly preferred embodiment, the cover element has at least one via which connects one of the contact surfaces of the capacitor and the coil body to the signal input or signal output.

The via contacts the support element either directly or via a conductive coating on the side, facing the cavity, of the cover element. If the capacitor includes a plurality of capacitors, the via connects one contact surface of each capacitor to the coil element.

In a particularly preferred embodiment, the cover element is a printed circuit board.

Preferably, an electrical input line is available for coupling the signal into the signal input, and an electrical output line is available for coupling the signal out of the signal output, which lines are preferably arranged on the outside of the cover element.

The signal input and the signal output can be arranged at a common contact point. The signal is then coupled out at the same port (contact point of the resonator to the input or output line) as it is coupled in (1-port). If the resonator is contacted as a 1-port, it can be used as a series or parallel resonant circuit.

Alternatively, the signal input and signal output can be arranged at different contact points. The signal is then coupled out at a different port than where it is coupled in. If the resonator is contacted as a 2-port, it is better suited as a bandpass filter.

In a special embodiment of the radio-frequency bandpass filter according to the invention, the capacitor is arranged within the cavity. This reduces electro-magnetic losses.

In this embodiment, the side, facing the cavity, of the cover element is preferably coated in an electrically conductive manner such that the coating comprises two partial coatings galvanically separated from one another, wherein one partial coating is galvanically connected to a first contact surface of the capacitor, and the other partial coating is galvanically connected to a second contact surface of the capacitor.

Alternatively or additionally, the capacitor can also be arranged outside the cavity. This has advantages for adjusting the resonator in an installed state. The cover element is then preferably coated with an electrically conductive material both on the side facing the cavity (bottom side) and on the side facing away from the cavity (top side). The degree of coating depends upon the quantity and arrangement of the capacitors outside the cavity.

Particularly in the embodiment in which the capacitor is arranged within the cavity, it is advantageous if an electrically conductive intermediate layer is arranged between the side, facing away from the cavity and the side, facing the cavity, of the cover element. The intermediate layer galvanically connects the radially outer contact surfaces of various capacitors in the arrangement with a low impedance. The intermediate layer serves to electromagnetically seal the cavity, in particular if the capacitance has capacitors within the cavity, since in this case, the side facing the cavity cannot be completely coated in an electrically conductive manner. This minimizes the stray field outside the cavity and therefore optimizes the RF tightness.

The galvanic connection is preferably made by blind hole contacts to the side, facing the cavity, of the cover element and by the vias of the cover element. Instead of blind hole contacts, vias can also be used.

The capacitance can include several parallel-connected capacitors. The capacitors are preferably arranged symmetrically, in particular rotationally symmetrically, around the resonator axis. The arrangement of the capacitors is preferably chosen so that they cover the smallest possible area. This effectively suppresses other (disturbing) resonances. A circular ring structure in which the capacitors are arranged as close to each other as possible is particularly preferred. The capacitance between the support element and any electrically conductive intermediate layer is thereby reduced.

In addition, it is also possible to arrange the capacitor completely or partially outside the cavity.

In a special embodiment, the capacitor is formed by an insulating disc coated with electrically conductive material, in particular a ceramic disc. The coating forms the contact surfaces of the capacitor.

In this embodiment, the insulator disc is preferably arranged between the support element and the cover element. The insulator disc is then coated in an electrically conductive manner on its two opposite sides and mechanically connects the cover element to the coil body. This allows a particularly compact design of the capacitance to be realized. The first contact surface is preferably electrically connected to the underside of the cover element.

The insulator disc is preferably designed as a ring with a central via.

In order to improve the filter effect, a particularly preferred embodiment of the radio-frequency bandpass filter according to the invention provides that the resonator arrangement comprise at least two resonators which are coupled to one another. In coupled resonators, the input line and output line are preferably connected to ports of different resonators.

Preferably, the resonators are coupled via their magnetic fields, wherein the cavities of two of the at least two resonators are connected to each other via openings in the coil bodies.

Alternatively, coupling via passive elements (coils, capacitors, lines) is also possible.

The center frequency of the RF bandpass filter according to the invention is preferably in the two-to three-digit MHz range. This can be achieved, for example, by the following characteristics for the resonator: Diameter of the cavity: 32 mm-90 mm, height of the cavity: 7 mm-22 mm, resulting inductance of the coil body: 1.5 nH-7.0 nH.

The power rating of the resonators is limited by the power rating of the capacitors and the insulation of the cover element. The RF bandpass filter according to the invention is suitable for outputs greater than 500 W and can therefore be advantageously used for HR (high resolution) and MAS (magic angle spinning) MR applications.

The invention also relates to an MR apparatus having a transmission and/or receiving arrangement with a previously described radio-frequency band-pass filter.

Furthermore, the invention relates to the use of a resonator with a signal input, a signal output, and an inductor that comprises an electrically conductive coil body having a cavity, as a radio-frequency bandpass filter for MR applications, in particular in a transmission and/or receiving arrangement of an MR apparatus. The resonator preferably has a constant resonance frequency and is closed in a substantially RF-tight manner.

Further advantages of the invention are found in the description and the drawing. Likewise, the features mentioned above and those detailed below can be used according to the invention individually or collectively in any combination. The embodiments shown and described are not to be understood as an exhaustive list, but rather have an exemplary character for the description of the invention.

### DETAILED DESCRIPTION OF THE INVENTION AND DRAWINGS

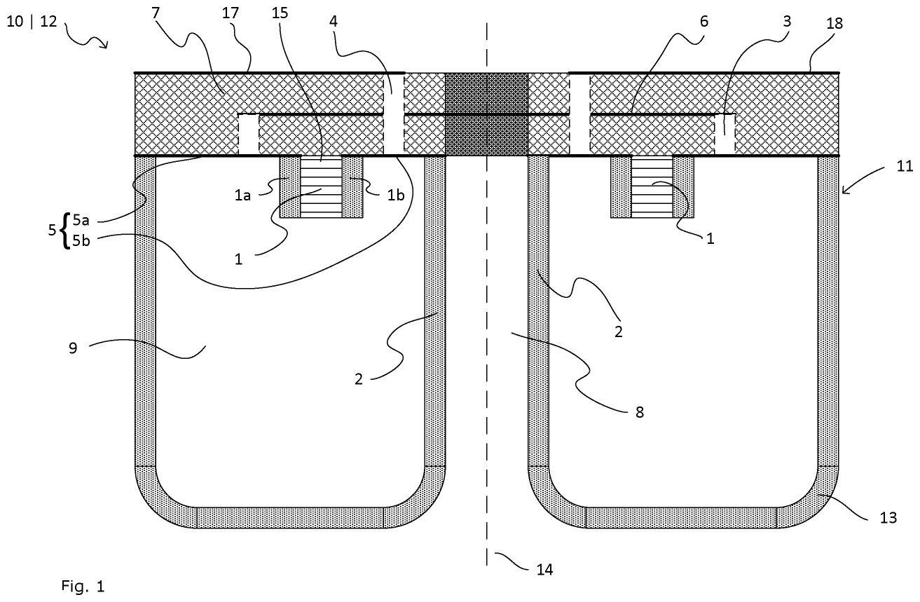

FIG. 1 shows a cross-section of a resonator of an RF bandpass filter according to the invention with capacitors arranged within the cavity.

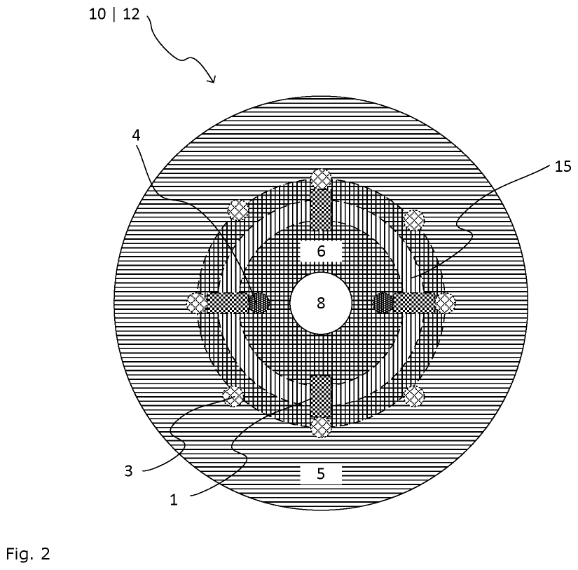

FIG. 2 shows the projection of the components of the resonator from FIG. 1.

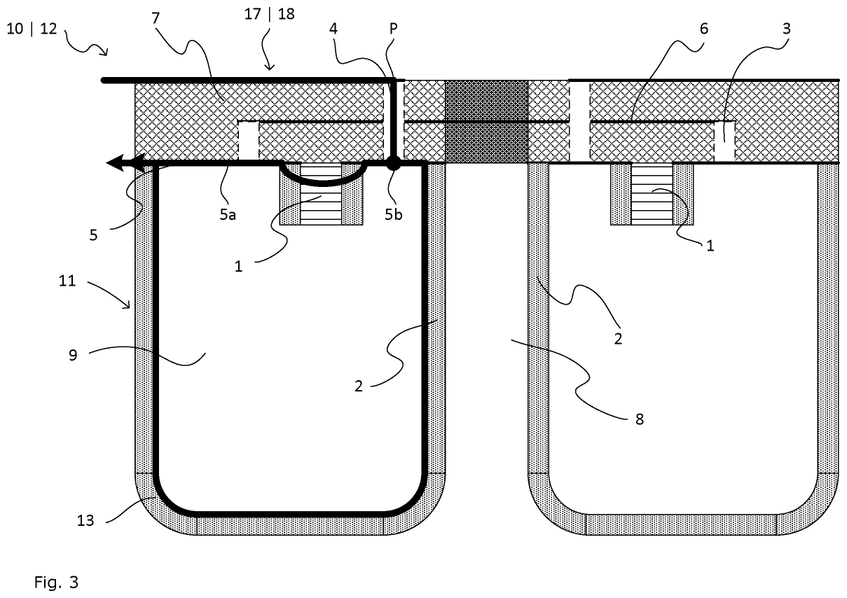

FIG. 3 shows a cross-section of a resonator arrangement with the resonator from FIG. 1 and a 1-port connection and a schematically portrayed signal flow.

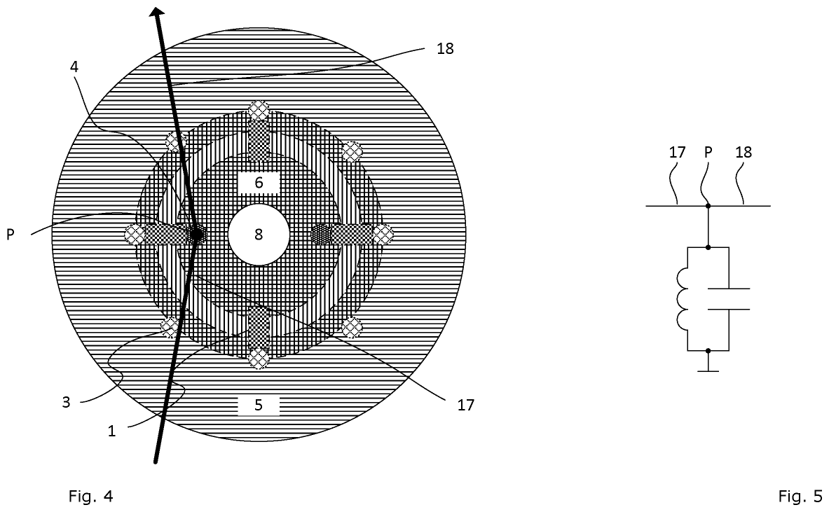

FIG. 4 shows the projection of the components of the resonator arrangement from FIG. 3.

FIG. 5 shows an equivalent circuit diagram of the resonator arrangement from FIG. 3.

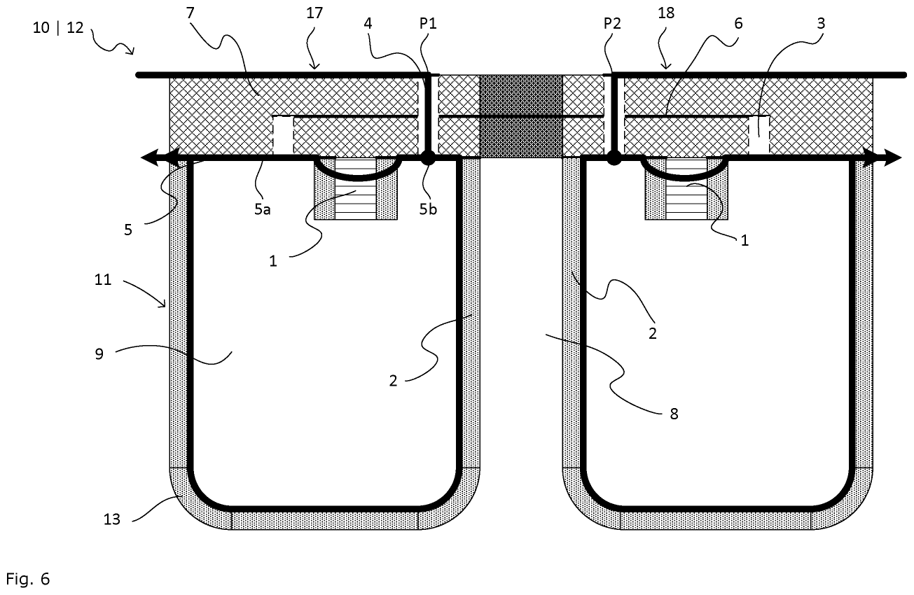

FIG. 6 shows a cross-section of a resonator arrangement with the resonator from FIG. 1 and a 2-port connection and a schematically portrayed signal flow.

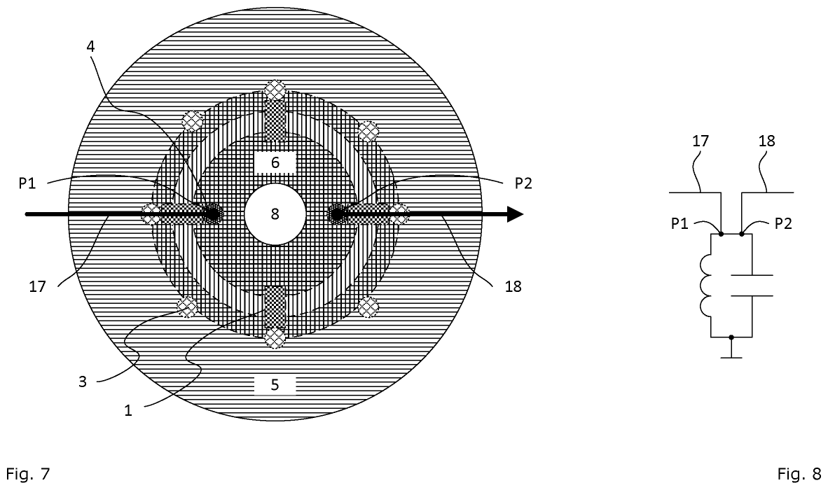

FIG. 7 shows the projection of the components of the resonator arrangement from FIG. 6.

FIG. 8 shows an equivalent circuit diagram of the resonator arrangement from FIG. 6.

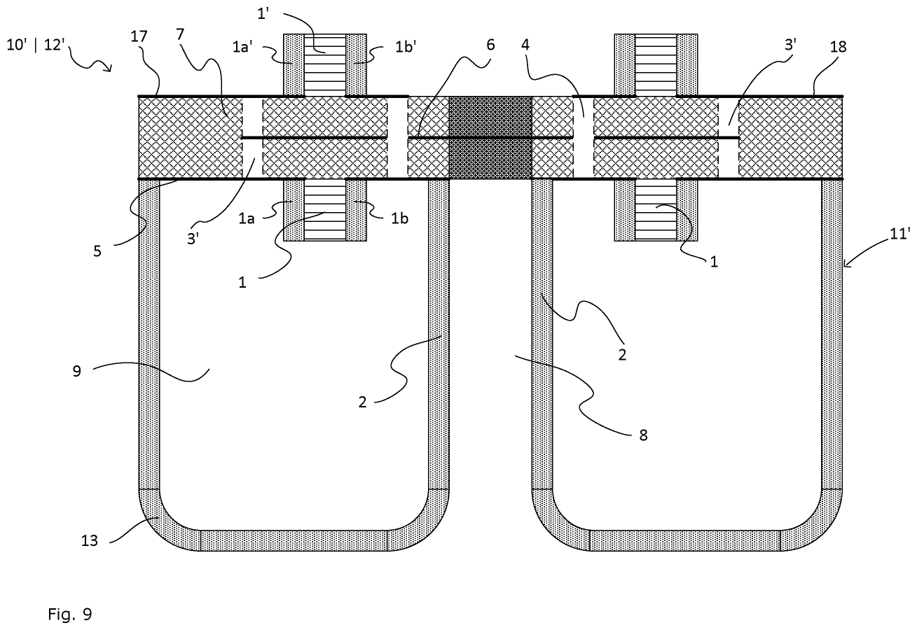

FIG. 9 shows a cross-section of a resonator of an RF bandpass filter according to the invention with capacitors arranged inside and outside the cavity.

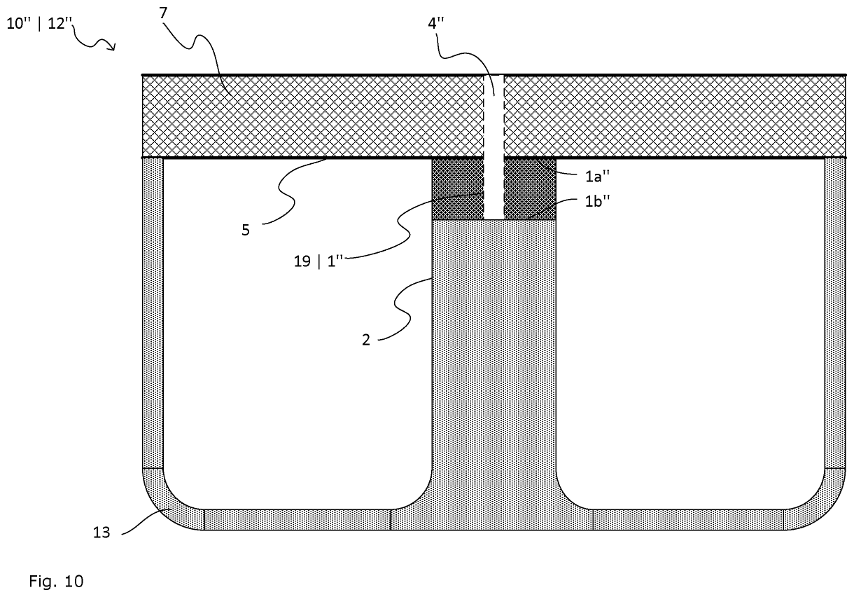

FIG. 10 shows a cross-section of a resonator of an RF bandpass filter according to the invention with a capacitor that is designed in the form of a central insulator disk.

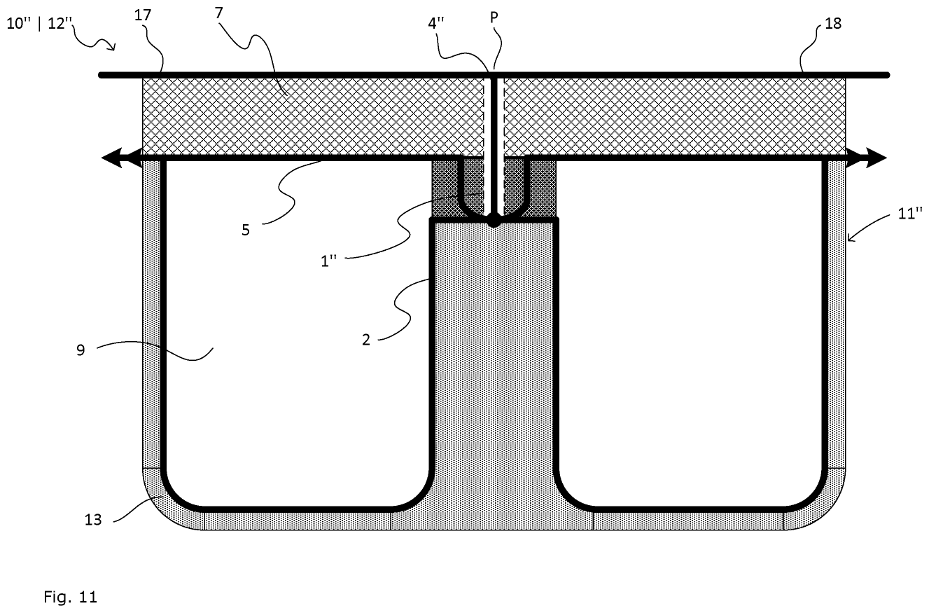

FIG. 11 shows the schematically portrayed signal flow in the resonator from FIG. 10.

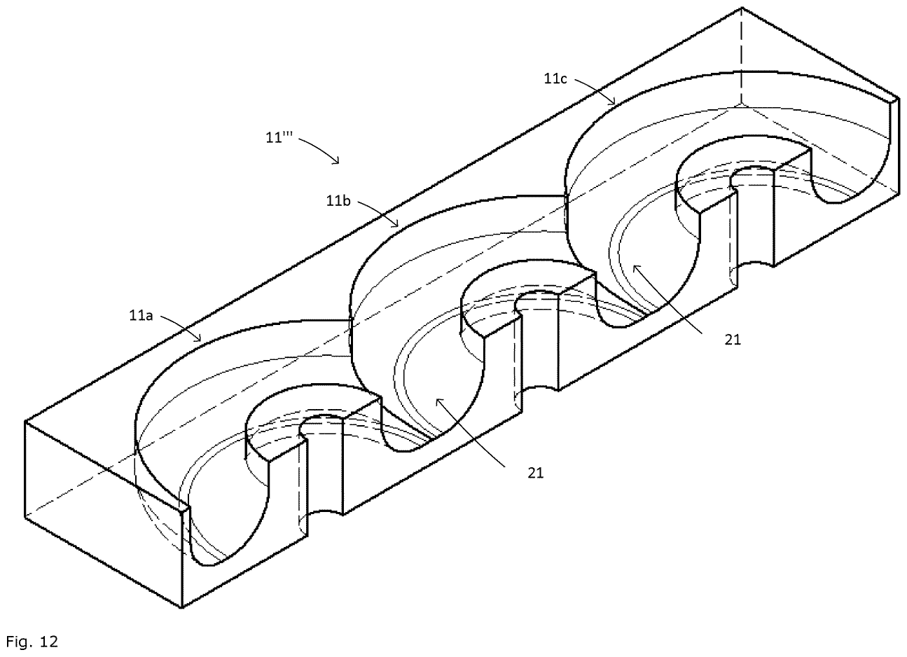

FIG. 12 shows a perspectival sectional view of a coil element of a particularly preferred embodiment of the RF bandpass filter with coupled resonators according to the invention.

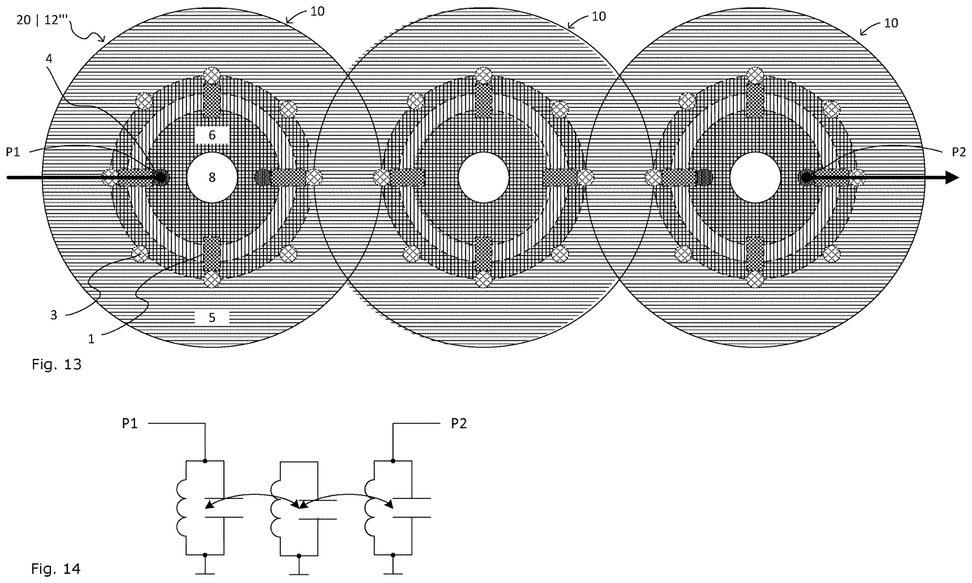

FIG. 13 shows the projection of the components of the resonator arrangement with coupled resonators.

FIG. 14 shows an equivalent circuit diagram of the resonator arrangement with coupled resonators.

FIG. 1 and FIG. 2 show a cross-section and a projection of a first embodiment of a resonator 10 of an RF bandpass filter 12 according to the invention. The resonator 10 comprises an inductor which is in the form of a coil body 11 having a cavity 9 and forms an oscillating circuit with the capacitors 1. The resonator 10 has a capacitance which is formed by capacitors 1 arranged within the cavity 9.

The coil body 11 of the shown embodiments is rotationally symmetrical, wherein the cavity 9 of the coil body 11 is substantially hollow-cylindrical with partially rounded edges in the lower region of the coil body 11, i.e., on the side of the coil body 11 opposite the cover element 7. The coil body 11 has a large electrically conductive surface and therefore a low electrical resistance.

The coil body 11 comprises a central electrically conductive support element 2 (radially inner, i.e., close to the axis, part of the U-shaped wall in FIG. 1 in cross-section), an outer wall 13 (lower and radially outer, i.e., far from the axis, part of the U-shaped wall shown in FIG. 1 in cross-section). The resonator 12 comprises a cover element 7 which closes the coil body 11 to form a housing.

The support element 2 and the outer wall 13 are made of an electrically conductive material. The support element 2 is preferably hollow and has a central through-opening 8. The cover element 7 is preferably a conductively coated insulator, in particular a printed circuit board, the underside of which (the side facing the cavity 9) is coated with an electrically conductive layer 5 (horizontal dashed line in FIG. 2), in particular coated. Between the two contact surfaces 1a, 1b of the capacitor 1, the underside of the cover element 7 has no electrically conductive coating. In the embodiment shown in FIG. 1 and FIG. 2, the electrically conductive layer 5 therefore comprises partial coatings 5a, 5b which are galvanically separated from each other, wherein the first partial coating 5a is galvanically connected to a first contact surface 1a of the capacitors 1 and is electrically at a reference potential (e.g., earth potential). The second partial coating 5b is galvanically connected to a second contact surface 1b of the capacitors 1. In general, the arrangement of the capacitors 1 is chosen such that they cover as small an area as possible in order to be able to suppress disturbing resonances effectively.

In order to optimally seal the cavity 9 electromagnetically despite the uncoated surface 15, an electrically conductive intermediate layer 6 (vertical dashed line in FIG. 2) can be provided between the top and the bottom of the cover element 7 (i.e., within the cover element 7), which layer galvanically connects the radially outer contact surfaces 1a of the capacitors 1 with a low impedance. In the embodiment shown in FIG. 1 and FIG. 2, this galvanic connection is made via the first partial coating 5a and blind hole contacts 3 open towards the cavity 9. Except for the openings in the via 4, the cavity 9 is electromagnetically sealed.

In the present embodiment, the capacitors 1 are arranged in a circular ring structure (i.e., at the same distance from a resonator axis 14) uniformly distributed around the resonator axis 14, as shown in FIG. 2. This allows the capacitors 1 to be arranged as close to each other as possible, thereby reducing the capacitance between the support element 2 and the electrically conductive intermediate layer 6. The partial coatings 5a, 5b of the electrically conductive layer are correspondingly ring-shaped and concentric and are separated by a layered ring-shaped surface 15. Alternatively, a single ring capacitor (with 2 ring-shaped contact surfaces) could also be provided.

The RF bandpass filter 12 according to the invention can be connected via ports P, P1, P2 to a component of an MR apparatus. For this purpose, the ports include a signal input for coupling in a signal to be filtered and/or a signal output for coupling out a filtered signal. The resonator 1 can be connected as a 1-port (signal input and signal output realized in a single port P), as shown in FIG. 3 and FIG. 4. A corresponding replacement circuit diagram is shown in FIG. 5. FIG. 6 and FIG. 7 show an alternative wiring via two separate ports P1, P2 (2-port). A corresponding replacement circuit diagram is shown in FIG. 8. Both connection options (1-port and 2-port) can be realized with all embodiments 12, 12′, 12″ described here and are shown using the example of the first embodiment 12 in FIGS. 3 to 7. In the first embodiment of the RF band filter 12, the ports P, P1, P2 are galvanically connected through vias 4 to the second partial coating 5b. The vias 4 are therefore in galvanic contact with the top and bottom of the cover element 7, but are not galvanically connected to the intermediate layer 6. An input line 17 and an output line 18 lead from the port P or the ports P1, P2 of the RF bandpass filter 12 to the component to be connected (not shown). The input line 17 and the output line 18 are preferably formed as conductor tracks on the side, facing away from the cavity, of the cover element 7.

FIG. 3 and FIG. 6 show the signal flow for the 1-port and 2-port variants of the RF bandpass filter 12. The RF signal to be filtered is coupled via the conductive parts of the surface of the cover element (input line 17) and passes through the cover element via the via 4. The RF signal splits at the lower end of the via 4. Radio-frequency components of an RF signal to be filtered, coupled in via the input line 17, are conducted from the signal input port P or P1 via the second partial coating 5b of the cover element 7, the capacitors 1, and the first partial coating 5a of the cover element 7 to a reference potential (e.g., ground potential). Low-frequency components of the RF signal to be filtered are conducted from the signal input port P or P1 via the second partial coating 5b of the cover element 7, the support element 2 along the inner wall of the cavity 9, the outer wall 13 of the coil body 11 to the underside of the cover element 7 to a reference potential (e.g., ground potential). For frequencies close to the resonant frequency of the resonator, the resonator is high-impedance. The corresponding components of the RF signal to be filtered oscillate in the resonator and can be coupled out of the RF bandpass filter 12 via the signal output port P or P2. Since the frequency of the RF signals to be filtered is in the MHz range, the signal transport takes place only via the electrically conductive surfaces of the resonator 2.

FIG. 9 shows a cross-section of a second embodiment of a resonator 10′ of an RF bandpass filter 12′ according to the invention with a coil body 11′ of a capacitance which is formed by capacitors 1 arranged inside the cavity 9 and by capacitors 1′ arranged outside the cavity 9.

The first contact surfaces 1a, 1a′ the capacitors 1, 1′ arranged inside and outside the cavity 9 are galvanically connected to each other via further vias 3′. Likewise, the second contact surfaces 1b, 1b′ of the capacitors 1, 1′ arranged inside and outside the cavity 9 are galvanically connected to one another. In contrast to the vias 4, the further vias 3′are not only galvanically connected to the top and bottom of the cover element 7, but also to the intermediate layer 6. The additional vias 3′ therefore also fulfill the function of the blind hole contacts 3 from FIG. 1. The input line 17 is galvanically connected to the second contact surfaces 1b of the capacitors 1, 1′and, if necessary, must be routed accordingly around the first contact surfaces 1b′ of the capacitors 1′ arranged outside the cavity 9. Alternatively, the input line 17 can also be led to the contact surface 1b′ via a further intermediate layer (not shown).

FIG. 10 shows a cross-section of a third embodiment of a resonator 10″ of an RF bandpass filter 12″ according to the invention with a capacitor 1″ which is designed in the form of a central insulator disc (e.g., an insulating foil or a ceramic disc) which is coated on both sides in an electrically conductive manner (capacitor 1″). The coatings of the insulator disc form contact surfaces 1a″, 1b″ of the capacitor 1″. In this embodiment, the underside 5 of the cover element 7 can be completely coated. The via 4″ is arranged centrally in this embodiment and contacts one of the two contact surfaces 1a″, 1b″ of the capacitor 1″ (here, for example, the lower contact surface 1b″). In contrast to the previously described embodiments, the via 4″ here contacts the support element 2 directly and not via a partial coating of the underside of the cover element 7. In this embodiment, the support element 2 is preferably solid.

FIG. 11 shows the corresponding signal flow by way of example for a 1-port variant. Radio-frequency components of an RF signal to be filtered, coupled in via the input line 17, are conducted from the port P through the via 4″, the capacitor 1″, the support element 2 along the inner wall of the cavity 9 of the outer wall 13 of the coil body 11″ to the underside of the cover element 7 to a reference potential (e.g., earth potential). Low-frequency components of an RF signal to be filtered, coupled in via the input line 17, are conducted from the port P through the via 4″ and the coating 5 on the underside of the cover element 7 to a reference potential (e.g., ground potential). The portion of the RF signal to be filtered that is not thereby filtered out is coupled out of the RF bandpass filter 12″ through the port P.

The resonators 10, 10′, 10″ can each function individually as an RF band-pass filter 12, 12′, 12″ according to the invention (simple resonator arrangement) or can be coupled to other resonators 10, 10′, 10″ to form a more complex resonator arrangement 20 in order to improve the filtering effect.

FIG. 12 shows a perspectival sectional view of a coil body 11′″ of a particularly preferred embodiment of the RF bandpass filter 12′″ according to the invention with such a resonator arrangement 20 with coupled resonators 10. The coil body 11″ comprises a plurality of partial coil bodies 11a, 11b, 11c which are electrically and mechanically connected to each other via openings 21 so that the magnetic fields can couple with each other, thereby achieving particularly good performance. The coil body 11′″ which comprises the three partial coil bodies 11a, 11b, 11c is preferably made of one piece (e.g., as a single milled part) and is preferably closed with a single cover element (not shown) which comprises three partial cover elements that have the components of the cover elements of individual resonators, as previously described.

FIG. 13 shows the projection of the components of the resonator arrangement 20 with coupled resonators 10. The two outer resonators are each contacted as a 1-port. The entire resonator arrangement 20 is therefore then again wired as a 2-port. An equivalent circuit diagram of the resonator arrangement 20 is shown in FIG. 14.

### LIST OF REFERENCE SIGNS

1 Capacitor inside cavity
1′Capacitor outside cavity
1″ Capacitor in support element
1a, 1a′, 1a″ First contact surface of the capacitor
1b, 1b′, 1b″ Second contact surface of the capacitor
2 Electrically conductive support element
3 Blind hole contact
4 Via
4″ Central via
5 Electrically conductive layer (coating)
5a First partial coating
5b Second partial coating
6 Electrically conductive intermediate layer
7 Cover element (PCB)
8 Through-opening
9 Cavity
10 Resonator with capacitor inside the cavity (simple resonator arrangement)
10′ Resonator with capacitor inside and outside the cavity (simple resonator arrangement)
10″ Resonator with capacitor in the support element (simple resonator arrangement)
11, 11′11″, 11″ Coil body
11a, 11b, 11c Partial coil body
12, 12′, 12″, 12″ RF bandpass filter
13 Outer wall
14 Resonator axis
15 Uncoated surface
17 Electrical input line
18 Electrical output line
20 Resonator arrangement with plurality of coupled resonators
21 Opening in the coil body
P Port with signal input and signal output
P1 Port with signal input
P2 Port with signal output

### LIST OF REFERENCES

[1] “Helical resonator bandpass filter”
   https://coil32.net/design/helix-resonator.html
[2] Garbacz et al.
   “A loop-gap resonator for chirality-sensitive nuclear magneto-electric resonance (NMER)”
   The Journal of Chemical Physics 145, 104201 (2016)
   DOI: 10.1063/1.4962285
   https://aip.scitation.org/doi/abs/10.1063/1.4962285
[3] Bobowski et al.
   “Permittivity and Conductivity Measured using a Novel Toroidal Split-Ring Resonator”
   https://arxiv.org/pdf/1901.00994.pdf
[4] Crypto Museum
   “Pulsed Cavity Resonant cavity microphone”
   https://www.cryptomuseum.com/covert/bugs/ec/cavity/index.htm
[5] Su et al.
   “Slot Antenna Integrated Re-Entrant Resonator Based Wireless Pressure Sensor for High-Temperature Applications”
   Sensors 2017, 17, 1963;
   DOI: 10.3390/s17091963
   https://www.mdpi.com/1424-8220/17/9/1963/htm
[6] Anand et al.
   “Air Cavities Integrated with Surface Mount Tuning Components for Tunable Evanescent-Mode Resonators”
   https://www.researchgate.net/publication/306117073
   DOI: 10.1109/MWSYM.2016.7539960

1. A magnetic resonance (MR) apparatus having a transmission and/or receiving arrangement of apparatus, with a radio-frequency bandpass filter comprising a resonator arrangement with a signal input, a signal output, and one or more resonators, wherein each resonator comprises:
an inductor, that comprises an electrically conductive coil body having a cavity that is closed in a substantially RF-tight manner;
a capacitor that is connected in parallel to the inductor and that is arranged within the cavity of the electrically conductive coil body;
a cover element that, together with the coil body, delimits the cavity within which the capacitor is arranged; and
an electrically conductive intermediate layer arranged between a side of the cover element facing away from the cavity and a side of the cover element facing the cavity.

2. The MR apparatus according to claim 1, wherein the cavity of the coil body is rotationally symmetrical.

3. (canceled)

4. The MR apparatus according to claim 31, wherein the cover element is electrically insulating and is at least partially provided with an electrically conductive material on the side facing the cavity.

5. The MR apparatus according to claim 1, wherein the cover element has at least one via which connects one of the contact surfaces of the capacitor and the coil body to the signal input or signal output.

6. The MR apparatus according to claim 1, wherein the cover element is a printed circuit board.

7. (canceled)

8. (canceled)

9. The MR apparatus according to claim 1, wherein the capacitor comprises a plurality of parallel-connected capacitors.

10. The radio MR apparatus according to claim 1, wherein the capacitor is formed by an insulating disc coated with electrically conductive material.

11. The MR apparatus according to claim 1, wherein the resonator arrangement comprises at least two resonators that are coupled to one another.

12. The MR apparatus according to claim 11, wherein the resonators are coupled via their magnetic fields, wherein the cavities of two of the one or more resonators are connected to one another via openings in the coil bodies.

13. The MR apparatus according to claim 1, wherein a center frequency of the RF bandpass filter is in a two-to three-digit MHz range.

14. (canceled)

15. (canceled)
